(19) United States
(12) Patent Application Publication
(10) Pub. No.: US 2001/0012599 A1
(43) Pub. Date: Aug. 9, 2001

(54) PRINTING MEDIA IN CYLINDRICAL FORM

(76) Inventors: REINER MICHELS, BEXBACH (DE); HARTMUT SANDIG, FRANKENTHAL (DE); ALFRED LEINENBACH, GONNHEIM (DE); THOMAS TELSER, WEINHEIM (DE)

Correspondence Address: KEIL & WEINKAUF, 1101 CONNECTICUT AVENUE N W, WASHINGTON, DC, 20036

(21) Appl. No.: 09/247,540

(22) Filed: Feb. 10, 1999

(30) Foreign Application Priority Data
Feb. 13, 1998 (DE) 29802468.3

(51) Int. Cl. G03F 7/26; B05C 1/08; B05D 1/28

(52) U.S. Cl. 430/273.1; 430/281.1; 430/283.1; 430/285.1; 430/306; 430/907; 430/910; 430/916; 430/944; 427/421; 427/428; 427/359; 118/108; 118/125; 118/307; 118/315; 118/316; 118/323; 118/258; 118/259

(57) ABSTRACT

A printing medium in cylindrical form consists of a dimensionally stable solid, partly hollow or hollow cylinder and a photopolymerizable crosslinkable cylinder layer which is applied in particular in part-layers by means of a coaxial coating apparatus and on which an IR radiation-sensitive layer is applied, preferably as a single layer, by means of a coaxial coating apparatus.

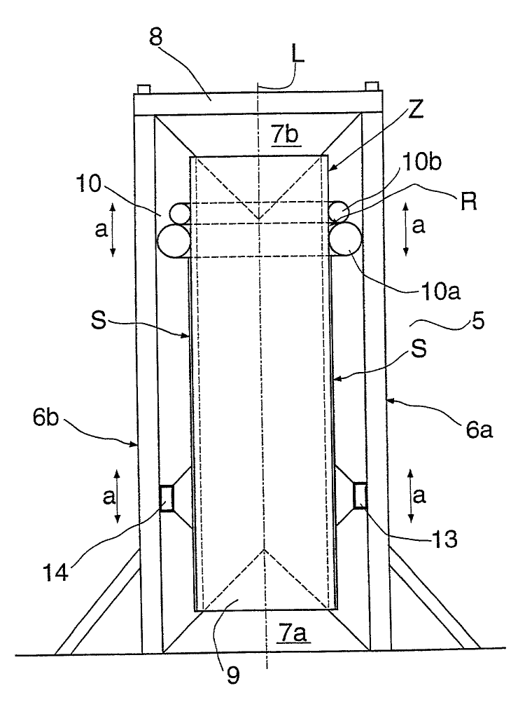

The result is an economically produced printing medium having uniform layer formations and layer thicknesses and the advantage of simple imagewise exposure and development and rapid use in the printing press.

The present invention relates to printing media in cylindrical form having a dimensionally stable solid, partly hollow or hollow cylinder and a layer which is crosslinkable on the outer cylinder surface by actinic radiation, can be washed out by developers after imagewise exposure and essentially comprises a mixture of at least one elastomeric binder, ethylenically unsaturated, copolymerizable organic compounds, a photoinitiator and, if required, further assistants.

Printing media of this type are either flat plates or cylindrical or part-cylinders.

Since the major part of print jobs carried out today are implemented using flexographic relief printing plates which have to be mounted on cylinders or as sleeves in printing presses, there is a need for simplification. A very critical cost and quality factor is in fact associated with the mounting of the ready-produced printing medium on the printing cylinder, mounting errors easily occurring and being evident, particularly in multicolor prints, by virtue of the fact that the prints lack crispness. Expensive mounting apparatuses and proof presses for registering monitoring and expensive careful manual mounting are required to remedy this. Since printing media are intended to be used several times and can therefore frequently be releasably bonded to the print cylinder, the printing medium may be damaged during removal.

European Patent Publication 767407 discloses a multilayer recording element, as described above, suitable for the production of flexographic printing plates by digital information transmission. It is thus possible, by digital information transmission, to expose the photopolymerizable layer imagewise with relatively little expense and then develop it. The following printing sleeves for direct use in the printing presses are also known as printing media.

Japanese Preliminary Published Application 58/052646 discloses a cylinder coated with a layer of photocurable resin, and a thin image-forming top layer. The photocurable resin layer is applied by means of an adhesion-promoting layer to a base layer on the outer cylinder surface. The top layer is exposed to laser beams and that part of the top layer which corresponds to the positive image is destroyed and blown away. This is followed by exposure and development of the photocurable resin layer, and the image is obtained for the flexographic printing process.

European Patent Publication 440079 discloses the provision of a calender arrangement for coating a cylinder, by means of which arrangement a layer of constant thickness and defined surface structure can be produced from photopolymerizable material on the cylinder to be coated.

European Patent Publication 766142 describes the provision of an IR radiation-sensitive layer as an outer layer on the photopolymerizable layer.

U.S. Pat. No. 5,262,275 states that the IR radiation-sensitive layer can be applied to a flexographic printing element by means of any known application method, such as spray coating, lamination, vapor deposition under reduced pressure or sputtering, the last-mentioned methods being useful in particular for metal layers.

Furthermore, European Patent Publications 650833 and 653300 disclose the production of layers on cylinder elements by means of coaxial, flexible coating apparatuses which may also be in the form of an O-ring. Such coating apparatuses are described exclusively for coating screen printing plate cylinders which have a very small wall thickness of 50-500 μm and 20-200 holes on a centimeter-wide lateral surface strip and which are provided with a layer of varnish. Owing to the low dimensional stability, the coaxial coating apparatus described is not very suitable for uniform layer application with a small layer thickness over the total outer cylinder surface. Other coaxial ring elements described are annular collars having a plurality of circumferential ribs and the varnish feed inbetween.

It is an object of the present invention to provide a printing medium in cylindrical form which is provided with at least one flexible photopolymeric layer and at least one advantageously formed IR-absorbing layer.

We have found that this object is achieved by a printing medium in cylindrical form having a dimensionally stable solid, partly hollow or hollow cylinder and a layer which is crosslinkable on the outer cylinder surface by actinic radiation, can be washed out by developers after imagewise exposure and essentially comprises a mixture of at least one elastomeric binder, ethylenically unsaturated, copolymerizable organic compounds, a photoinitiator and, if required, further assistants, if a layer sensitive to IR radiation is applied to the surface of the crosslinkable cylinder layer by means of a coating apparatus coaxially with and along the cylinder axis, the coating apparatus comprising a flexible ring element which is adapted to the circumference of the crosslinkable cylinder layer and is in close contact along at least one internal circumference with the circumference of the outer crosslinkable cylinder layer, and the layer sensitive to IR radiation being a layer which is soluble or dispersible in a developer and which contains, in a film-forming binder having elastomeric character, at least one finely distributed substance having a high absorption in the IR wavelength range.

The IR radiation-sensitive layer applied coaxially to the cylinder layer ensures that layers are available which are more uniform and thinner than in the case of the known printing media. This makes it possible to produce the printing relief directly on the cylinder at relatively little expense since substantially lower laser powers are required for removing the undesired IR layer and less IR absorber material is required in conjunction with shorter laser times and hence higher productivity.

It is advantageous in practice if the surface of the applied crosslinkable cylinder layer is coated with the IR radiation-sensitive layer by means of at least one coating apparatus which is arranged coaxially with the cylinder axis and has been moved coaxially and in the axial direction over the cylinder layer with a predetermined format.

In a particularly simple practical embodiment, the coating apparatus contained at least one elastic O-ring whose inner circumference rests against the outer cylinder layer circumference and which can roll along in the axial direction of the cylinder layer.

In an alternative embodiment, the coaxial coating apparatus may have coaxially arranged dispersion application nozzles facing the surface of the crosslinkable cylinder layer.

It is advantageous in practice if the printing medium has an IR radiation-sensitive dispersion layer having a thickness of from about 100 Å to about 2.5 μm, in particular from about 1.5 to about 2.0 μm.

The dimensionally stable hollow cylinder may advantageously be a cast or injection molded, wound or drawn tube element.

Advantageously, the viscosity of the applied IR radiation-sensitive dispersion may be from about 50 to about 500, in particular from about 100 to about 200, mPas, with the result that a very uniform thin layer was applied.

It is advantageous if the layer crosslinkable on the outer cylinder surface by actinic radiation is also applied coaxially with the cylinder axis in the form of a plurality of part-layers one on top of the other by means of a coating apparatus, the coating apparatus comprising a flexible ring element which is adapted to the circumference of the lateral cylinder surface and is in close contact along at least one inner circumference with the circumference of the lateral cylinder surface or of the applied part-layers. It is also advantageous for the formation of the cylinder layer if the ring element contains at least one O-ring.

It is furthermore advantageous if the viscosity of the applied part-layers crosslinkable by actinic radiation is less than 10000 Pas, and in particular from about 5000 to about 8000 mPas.

It is also advantageous for a dispersion layer which is sensitive to IR radiation and has a thickness of from 100 Å to 2.5 μm to be applied to the outer circumference of the crosslinkable part-layers.

The dimensionally stable hollow cylinder as a substrate for the photopolymerizable cylinder layer may consist of metals, such as steel, aluminum, copper or nickel, or suitable alloys thereof, or of plastics, such as polyethylene terephthalate, polybutylene terephthalate, polyamide and polycarbonate, woven fabrics and nonwovens, such as woven glass fiber fabrics and composite materials comprising glass fibers, mineral fibers or plastics, in particular those capable of being recycled. The cylinder layer crosslinkable by actinic radiation is a material essentially comprising a mixture of at least one elastomeric binder, one or more ethylenically unsaturated copolymerizable organic compounds, a photoinitiator or a photoinitiator system and, if required, other assistants and capable of being washed out by a developer after imagewise exposure.

Examples of suitable elastomeric binders are elastomeric polymeric binders, for example polyalkadienes, vinylaromatic/alkadiene copolymers and block polymers, alkadiene/acrylonitrile copolymers, ethylene/propylene copolymers, ethylene/propylene/alkadiene copolymers, ethylene/acrylic acid copolymers, alkadiene/acrylic acid copolymers, alkadiene/acrylate/acrylic acid copolymers and ethylene/(meth)acrylic acid/(meth)acrylate copolymers.

Very particularly suitable are elastomers which contain conjugated alkadienes, such as butadiene or isoprene, and styrene as polymerized units. The elastomeric binder is contained in the photopolymerizable cylinder layer in an amount of from 50 to 95, preferably from 50 to 90, % by weight, based on the total amount of the components contained in the cylinder layer.

Furthermore, the photopolymerizable relief-forming cylinder layer used according to the invention contains conventional and known copolymerizable ethylenically unsaturated organic compounds which are compatible with the polymeric binders, in an amount of from 1 to 60, advantageously from 2 to 50, and in particular from 3 to 40, % by weight, based on the total amount of the cylinder layer. The term “compatible” indicates that the relevant monomers are readily miscible with the elastomeric binder such that no haze or stria are caused in the relevant photopolymerizable relief-forming cylinder layer. Examples of suitable monomers are the conventional known acrylates and methacrylates of monohydric or polyhydric alcohols, acrylamides and methacrylamides, vinyl ethers and vinyl esters, allyl ethers and allyl esters and fumaric or maleic diesters, in particular the esters of acrylic and/or methacrylic acid with monohydric and preferably polyhydric alcohols, for example esters of acrylic or methacrylic acid with ethanediol, propanediol, butanediol, hexanediol, oxaalkanediols, eg. diethylene glycol, or esters of acrylic or methacrylic acid with trihydric or polyhydric alcohols, eg. glycerol, trimethylolpropane, pentaerythritol or sorbitol. Examples of particularly suitable monofunctional and polyfunctional acrylates or methacrylates are butyl acrylate, butyl methacrylate, 2-ethylhexyl acrylate, lauryl (meth)acrylate, hexanediol diacrylate, hexanediol dimethacrylate, ethylene glycol di(meth)acrylate, butanediol 1,4-di(meth)acrylate, neopentylglycol di(meth)acrylate, 3-methylpentanediol di(meth)acrylate, 2-hydroxypropyl (meth)acrylate, 2-hydroxyethyl (meth)acrylate, 1,1,1-trimethylolpropane tri(meth)acrylate, di-, tri- and tetraethylene glycol di(meth)acrylate, tripropylene glycol di(meth)acrylate or pentaerythrityl tetra(meth)acrylate, and furthermore poly(ethylene oxide) di(meth)acrylate, ω-methyl-poly(ethylene oxide)-α-yl (meth)acrylate, N,N-diethylaminoethyl acrylate, a reaction product of 1 mol of glycerol, 1 mol of epichlorohydrin and 3 mol of acrylic acid, and glycidyl methacrylate and bisphenol A diglycidyl ether acrylate.

Mixtures of photopolymerizable ethylenically unsaturated organic compounds, and, for example, mixtures of monofunctional (meth)acrylates, eg. hydroxyethyl methacrylate, with polyfunctional (meth)acrylates of the abovementioned type are also suitable.

In addition to the (meth)acrylates, derivatives of (meth)acrylamides, for example N-methylol(meth)acrylamidoethers of polyols (eg. glycol), are also suitable.

In addition to elastomeric binders and copolymerizable ethylenically unsaturated monomeric compounds, the cylinder layer crosslinkable by actinic radiation (=photosensitive recording layer) contains one or more photoinitiators, for example benzoin or benzoin derivatives, such as benzoin ethers of straight-chain or branched monoalcohols of 1 to 6 carbon atoms, eg. benzoin methyl ether, benzoin ethyl ether, benzoin isopropyl ether, benzoin n-butyl ether or benzoin isobutyl ether, symmetrically or unsymmetrically substituted benzil acetals, such as benzil dimethyl acetal or benzil 1-methyl 1-ethyl acetal, diarylphosphine oxides, such as 2,4,6-trimethylbenzoyldiphenylphosphine oxide or 2,6-dimethoxybenzoyldiphenylphosphine oxide, or acyldiarylphosphine oxides according to German Laid-Open Application DE-A 29 09 992, or hydroxypropanones, such as 1-phenyl-2-methyl-2-hydroxy-1-propanone, and 1-hydroxycyclohexyl phenyl ketone. They may be used alone or as a mixture with one another or in combination with coinitiators, for example benzoin methyl ether with triphenylphosphine, diacylphosphine oxides with tertiary amines or acyldiarylphosphine oxides with benzil dimethyl acetal.

In the mixtures, they are used in an amount of from 0.001 to 10, advantageously from 0.1 to 5, in particular from 0.3 to 2, % by weight, based on the total amount of the photosensitive cylinder layer, the amount being determined, inter alia, by the presence of photopolymerizable monomers.

Further assistants which may, if required, be added—in general in an amount of from 0.001 to 2% by weight, based on the total amount of the photosensitive cylinder layer—are thermal polymerization inhibitors which have no significant self-absorption in the actinic range in which the photoinitiator absorbs, eg. 2,6-tert-butyl-p-cresol, hydroquinone, p-methoxyphenol, β-naphthol, phenothiazine, pyridine, nitrobenzene, m-dinitrobenzene or chloranil; thiazine dyes, such as Thionine Blue G (C.I. 52025), Methylene Blue B (C.I. 52015) or Toluidine Blue (C.I. 52040), or N-nitrosamines, such as N-nitrosodiphenylamine, or the salts, for example the potassium, calcium or aluminum salts, of N-nitrosocyclohexylhydroxylamine.

Suitable dyes, pigments or photochromic additives may also be added to the photosensitive mixture of the recording layer (A) in an amount of from 0.0001 to 2% by weight, based on the mixture. They serve for controlling the exposure properties, for identification, for direct monitoring of the exposure result or for esthetic purposes. A precondition for the choice and the amount of such additives is that they interfere with the photopolymerization of the mixtures to as little an extent as the thermal polymerization inhibitors. For example, the soluble phenazinium, phenoxazinium, acridinium and phenothiazinium dyes, such as Neutral Red (C.I. 50040), Safranine T (C.I. 50240), Rhodanil Blue, the salt or amide of Rhodamine B (C.I. 45170) and Nile Blue (C.I. 51180), the salt or amide of Methylene Blue B (C.I. 52015), Thionine Blue G (C.I. 52025) or Acridine Orange (C.I. 46005), and also Solvent Black 3 (C.I. 26150) are suitable. These dyes may also be used together with a sufficient amount of a reducing agent which does not reduce the dye in the absence of actinic light but is capable of reducing the dye in the excited electronic state during exposure. Examples of such mild reducing agents are ascorbic acid, anethole, thiourea, eg. diethylallylthiourea, in particular N-allylthiourea, and hydroxylamine derivatives, in particular salts of N-nitrosocyclohexylhydroxylamine, preferably the potassium, calcium and aluminum salts. As mentioned, the latter can simultaneously serve as thermal polymerization inhibitors. The reducing agents can in general be added in amounts of from 0.005 to 5% by weight, based on the mixture, in many cases the addition of from 3 to 10 times the amount of concomitantly used dye having proven useful. In addition, the formulation may also contain from 1 to 20, preferably from 3 to 10, % by weight of bases which partially or completely neutralize the acid functions of the ethylene/acrylic acid copolymer. Suitable bases are, for example, alkali metal hydroxides, alkali metal alcoholates and amines and alkanolamines. Particularly suitable bases are monoethanolamine, diethanolamine, butylethanolamine and triethanolamine.

The production of the photopolymerizable relief-forming cylinder layer used according to the invention from its components is carried out in general by mixing the components by known mixing methods or by processing the mixture to give the IR radiation-sensitive layer with the aid of known techniques, such as casting from solution, calendering or extrusion, it also being possible for these measures to be combined with one another in a suitable manner.

The cylinder layer crosslinkable by actinic radiation generally has a thickness of from 200 to 8000 μm, in particular from 500 to 6000 μm. A further thin oxygen-permeable layer which may have a thickness of from 1 to 5 μm and renders the surface of the photosensitive cylinder layer nontacky can be applied to said cylinder layer. The layer which is sensitive to IR radiation and soluble or dispersible in a developer and contains, in a film-forming binder having elastomeric character, at least one finely distributed substance which has high absorption in the wavelength range from 750 to 20 000 nm and an optical density of ≧2.5 in the actinic range is applied to said oxygen-permeable layer or preferably directly to the cylinder layer crosslinkable by actinic radiation. Developers here may be water and water/alcohol or organic solvent (mixtures). Binders having elastomeric character which are suitable for the IR radiation-sensitive layer are polymers, particularly copolymers, which are either water-soluble or dispersible in water or water/alcohol mixtures or those which are soluble or dispersible in organic solvents or solvent mixtures. Suitable alcohols in the water/alcohol mixtures are methanol, ethanol, n-propanol and isopropanol.

Examples of binders soluble or dispersible in water or in water/alcohol mixtures and having an elastomeric character are polyvinyl alcohol/polyethylene glycol graft copolymers (eg. Mowiol® GE 597 from Hoechst Aktiengesellschaft, Germany), which are obtainable by grafting vinyl acetate onto polyethylene glycol having molecular weights of from 1000 to 50000 and then carrying out hydrolysis to a degree of hydrolysis of from 80 to 100%.

Examples of binders soluble or dispersible in organic solvents or solvent mixtures and having elastomeric character are thermoplastic polyamide resins which can be prepared, for example, by conventional polycondensation and are marketed, for example, under the name Macromelt® by Henkel Aktiengesellschaft, Germany. All the abovementioned products are described in detail in the respective relevant company publications.

The film-forming binders having elastomeric character in the IR layer contain, in finely distributed form, substances which have a high absorption in the IR range. Examples of such substances are various finely divided carbon black types, for example color black FW 2000, Special Black 5, Printex®U from Degussa Aktiengesellschaft, Germany, having a mean primary particle size of 13-30 nm. Solutions which contain binders having elastomeric character and substances having high IR absorption and which are either applied directly and uniformly to the cylinder layer and dried or cast on a film, dried and laminated with the cylinder layer are advantageously used. The film can, if required, be removed.

A peelable film transparent to actinic light, a cover sheet which has a thickness from 5 to 300 μm and consists, for example, of polyethylene or polyethylene terephthalate, may also be applied to the IR layer.

The processing steps which comprise exposure to actinic light, development and drying are described in detail, for example, in the Nyloflex® working instructions (IIR 340705/1185) from BASF Drucksysteme GmbH, Germany.

The layer (B) sensitive to IR radiation can be inscribed imagewise by means of an IR laser, preferably by means of an Nd-YAG laser. This is carried out on the cylinder. An IR-sensitive layer which consists of an elastomeric binder and IR absorbers dispersed therein prove advantageous here. The digital information transmission is followed by uniform exposure to actinic light. This can be effected either on the drum of the IR laser, or the plate is removed and the uniform exposure carried out in a conventional flat-plate exposure unit (eg. FIII exposure unit from BASF Drucksysteme GmbH). The recording element is then developed. Commercial continuous or cylindrical washers, as offered, for example, by BASF Drucksysteme GmbH, may be used for this purpose. Depending on the chemistry of the binder having elastomeric character which is used in the IR layer, this layer is, if required, removed in a predeveloper if said layer is insoluble or not dispersible in the developer of the cylinder layer. Thus, the following developer combinations have proven advantageous, depending on the chemistry of the IR layer:

| Binder of the IR | Solubility of the | Developer for |
|---|---|---|
| layer: | cylinder layer | IR layer |
| Polyvinyl | organic solvent or | water or |
| alcohol/poly- | mixtures of organic | water/alcohol |
| ethylene glycol | solvents | |
| graft copolymer | | |
| | water or aqueous | water or water/alcohol |
| | systems | |
| thermoplastic | organic solvent or | organic solvents or |
| polyamide resin | mixtures of organic | solvent mixtures (no |
| | solvents | predevelopment |
| | | necessary) |

Organic solvent mixtures suitable as developers are, for example, perchloroethylene/butanol mixtures or Nylosolv® (hydrocarbon/alcohol mixture).

(Nyloflex® and Nylosolv® are registered trademarks of BASF Drucksysteme GmbH, Germany)

The predevelopment step may be carried out in a very simple manner, for example in commercial plush washers from BASF, which are very suitable.

After development, the recording material is also subjected to a drying step. Here, the developer still contained in the relief layer is removed. Here too, all commercial dryers, for example including those from BASF Drucksysteme GmbH, are suitable.

In the uniform exposure to actinic light, the presence of atmospheric oxygen surprisingly proves very advantageous.

The photopolymerization is suppressed at the edges of the image parts—which are subsequently the printing parts—by the oxygen which is known to act as a photopolymerization inhibitor; in the center of the image parts, the inhibitory effect is not so strong since sufficient actinic light is available. Thus, the diameter of each image element is substantially reduced. In other words, instead of 1:1 transmission from the mask produced by IR ablation, less extensive transmission is achieved. During printing, this has the great advantage that a much smaller increase in tonal value results. This is very advantageous since, in the flexographic printing process, the printing plate is inked by means of an engraved roller and the ink is then transferred from the printing plate to the printing stock, the printing stock being guided around a hard impression cylinder. Here, the flexographic printing plate is compressed, this squeezing process causing the printed area to be larger than the inked area on the printing plate. The term increase in tonal value is used in this context. With the use of the photosensitive recording materials described in U.S. Pat. No. 5,262,275 and having a barrier layer between the IR-sensitive layer and the layer crosslinkable by actinic light, the inhibitory effect of the atmospheric oxygen is not so strong by far; in the printing process the tonal value of a printing plate thus produced will also increase correspondingly.

The hollow cylinder may be equipped with a flexographic printing plate by adhesively bonding the latter on said cylinder and eliminating the joint gap and applying the IR-sensitive layer according to the present invention.

It is also possible to apply the photopolymerizable layer directly or, if required, with an intermediate adhesion-promoting film as a substrate to the outer cylindrical surface of the hollow cylinder, likewise by the conventional methods known above for the IR layer. It is in principle also possible to use a novel coaxial coating or application apparatus for the application of this layer too.

Regardless of the method of application of the photopolymerizable layer or plate with coating, according to the invention the photopolymerizable cylinder layer is coated by means of a coaxially guided ring or cylinder element according to the schematic diagram in the FIGURE.

The FIGURE shows a retaining and guide frame 5, essentially consisting of two perpendicular guide rails 6a, b and, mounted thereon, two retaining cones 7a and 7b, of which retaining cone 7b is provided on a crossbeam 8 which is detachably fastened to the rails 6a, b by means of screw elements. When retaining cone 7b is removed, the hollow cylinder 9, with or without photopolymer layer (cylinder layer), can be inserted into the frame 5 and the annular coating apparatus 10 can be mounted on the outer cylindrical surface of the hollow cylinder 9 or of the preferably preexposed cylinder layer. The coating apparatus 10 consists essentially of an O-ring 10a and a dispersion application unit 10b which is arranged adjacent to the O-ring 10a and is advantageously also movable therewith. The application of the dispersion is to be effected in the annular gap R between outer cylinder surface Z and O-ring 10a and takes place at atmospheric pressure or at a slight outlet pressure, depending on the speed of movement of the apparatus 10. As shown, the longitudinal axis L of the hollow cylinder 9 coincides, for example, with the central axis of the entire apparatus. It is advantageous that the apparatus 10 moves coaxially with the longitudinal axis L over the lateral cylinder surface, said apparatus being movable between the guide rails 6a and b and the outer cylinder surface Z, closely guided by means of a movement unit not shown, as indicated by double-head arrows a. The speed of movement of the apparatus 10 can be adapted to the required dispersion volume to be metered by the application unit 10b by a control and metering means. It is thus also possible to set any desired layer thicknesses, for example from about 100 Å to about 2.5 μm, in particular from about 1.5 to about 2.0 μm, for the IR coating. As stated above, layer thicknesses of from 0.2 to 8 mm, in particular from about 0.5 to about 6 mm, are required in the case of an application of the photopolymerizable cylinder layer, advantageously a plurality of part-layers being capable of being applied by means of this application apparatus until the desired total layer thickness of the photopolymerizable layer is reached. With the aid of the flexible and advantageously elastic ring or cylinder element 10a as coating apparatus 10, uniform layers of constant and adjustable layer thickness are surprisingly obtained. The lower region in which the layer or the layers have already been applied is denoted by S in the FIGURE. The material of the ring or cylinder element is elastomeric, ie. consists of natural rubber or elastomers, with possible corrosion-inhibiting additives.

The ring element 10a rests against the circumference of the outer cylinder surface Z with such a small clamping force that, in the stationary state of the apparatus 10, the dispersion cannot pass the ring element 10a and, when the ring element 10a is moving, a meterable amount of dispersion flows over and thus establishes the layer thickness. The viscosity of the dispersion was from about 50 to about 500 mPas in the case of the IR layer and was less than 10000 mPas, in particular from about 3000 to about 6000 mPas in the case of the photopolymerizable cylinder layer. Similarly uniform layers are also achievable by means of spray application. In this case, the coating apparatus 10 should be replaced by a spray ring 13 which is indicated schematically and likewise moves in the directions a) coaxially with the longitudinal axis L over the outer cylinder surface z at a distance. The spray ring 13 is formed with coaxially arranged nozzles (not shown) facing the outer cylindrical surface of the cylinder. The spray cone is denoted by 14. The achievable total layer thicknesses are of the same order of magnitude as stated above when the same dispersion of the same viscosity is used.

After the production of the photopolymerizable layer, the cylinder layer, the latter was preexposed, in order to obtain a surface which was relatively hard on the outside, and it could then be provided with the IR layer in the same coating apparatus or in an apparatus operating according to the same principle.

In both cases, if only the IR layer was produced according to the invention or the IR layer was applied to a photopolymerizable layer likewise produced according to the invention, this was followed by the IR laser exposure to produce the print image and the subsequent UV exposure of the photopolymerizable cylinder layer and its development and, if required, postexposure to produce the printing medium in cylinder form.

Details are described below in Examples.

### EXAMPLE 1

A metal or glass fiber-reinforced sleeve which is suitable for the respective printing materials, in this case polyethylene, is used as a hollow cylinder. Such sleeves are commercially available for all possible applications. To ensure that the surface of the sleeve is firmly bonded to the photopolymeric layer, a conventional adhesion promoter, for example a mixture of adhesive-forming components or a commercial double-sided self adhesive tape, may be applied to the outer surface of the sleeve. flexographic printing plate FAR 284 from BASF Drucksysteme GmbH is applied as the photopolymeric layer. In accordance with the materials described above, this layer contains:

| | | |
|---|---|---|
| a styrene/isoprene/styrene | 80 | parts |
| 3-block copolymer as elastomeric binder | | |
| a styrene copolymer | 2.5 | parts |
| white oil | 5.5 | parts |
| a hexanediol diacrylate | 6.7 | parts |
| a hexanediol methyacrylate | 3.3 | parts |
| as monomers compatible with the binder | | |
| and | | |
| a UV initiator | 1.0 | part |
| and | | |
| an antioxidant | 1.0 | part |

The flexographic printing plate is produced by extruding the melt of the above formulation between two PET films (see above) with subsequent calendering. To ensure that the upper and lower film is peelable for subsequent mounting, a siliconized film is applied. The flexographic printing plate thus produced is cut accurately to size and is adhesively bonded with its ends abutting on the hollow cylinder and the ends are then fused together so as not to form a gap. The applied photopolymeric layer is then surface-treated and the IR radiation-sensitive dispersion layer, consisting of about equal parts of carbon black pigment (Printex® U) and a polyvinyl alcohol-based graft copolymer having a high degree of hydrolysis, is applied by means of the novel apparatus described.

The applied IR-sensitive layer is then exposed imagewise to an Nd:YAG laser (wavelength of the emitted light 1065 nm). The point diameter of the IR beam was from about 5 to about 20 nm. The subsequent uniform UV exposure is then carried out on a rotary, cylindrical exposure unit and subsequent development in a drum-type brush washer with nylosolv® developer solution. Drying and detackifying of the printing cylinder using known apparatuses and methods then follow.

The chosen print motif had a screen ruling of 50 lines/cm and possessed a tonal range of from 3 to about 95%. The flexographic printing cylinder as a novel printing medium was mounted on a commercial flexographic printing press and a polyethylene film was printed using alcohol ink. The result was rated visually: surprisingly, register, transfer of tonal value, contrast and length of print run were rated as good.

### EXAMPLE 2

The procedure was as in Example 1, except that a black printing ink was applied as the IR-sensitive layer. This was the printing ink Pyroflex V12P from BASF Drucksysteme GmbH. The chosen print motif corresponded to that of Example 1. The flexographic printing cylinders or sleeves were mounted on a commercial flexographic printing press as in Example 1 and polyethylene film was printed using alcohol inks. The printed copies were then rated visually. The direct comparison with Example 1 made it clear that register, transfer of tonal value, contrast and length of print run were identical to the result of Example 1.

### EXAMPLE 3

A sleeve as in Example 1 was used as the hollow cylinder and was equipped with adhesive. The photopolymeric flexographic layer had the following composition:

| | | |
|---|---|---|
| a styrene/butadiene/styrene | 83 | parts |
| 3-block copolymer as an elastomeric binder | | |
| a styrene copolymer | 5 | parts |
| a white oil | 5 | parts |
| as a monomer compatible with the binder | | |
| a hexanediol diacrylate | 5 | parts |
| a UV initiator | 1 | part |
| an antioxidant | 1 | part |

A layer which was 800 nm thick when dry was applied to the hollow cylinder from solution in toluene having a solids content of about 45% by application once or a plurality of times using the novel apparatus. The viscosity of the solution of photopolymer in toluene was from 3000 to 6000 mpas. Drying at from about 50 to 70° C. was required between the individual application processes. By repeated coating, a layer thickness of from about 1.6 to 8 mm, with a tolerance of less than 20 μm, was achieved.

The flexographic layer produced according to the invention on the hollow cylinder was then provided with the IR-sensitive dispersion layer as described in Example 1, exposed imagewise to the same laser, exposed to UV radiation, developed and dried and mounted on a commercial flexographic printing press, and polyethylene films were printed with the print motif from Example 1 and using alcohol inks. The final visual rating showed that the quality of the register, transfer of tonal value, contrast and length of print run corresponded to the excellent results of Example 1.

The Examples describe the production of the novel photosensitive cylinder layers and the excellent printed copy obtained therewith. In the Examples, parts and percentages are by weight, unless stated otherwise.

A continuous cylindrical printing medium which can be used without a gap or other disturbance of the printing surface directly in the printing press and can be employed for printing was obtained.

The present invention relates to a printing medium in cylindrical form consisting of a dimensionally stable solid, partly hollow or hollow cylinder and a photopolymerizable crosslinkable cylinder layer which in particular is applied in part-layers by means of a coaxial coating apparatus and on which an IR radiation-sensitive layer is applied, preferably as an individual layer, by means of a coaxial coating apparatus.

The result is an economically produced printing medium having uniform layer formations and layer thicknesses and the advantage of the simple imagewise exposure and development and the rapid use in the printing press.

We claim:

1. A cylindrical printing medium having a dimensionally stable solid, partly hollow or hollow cylinder and a layer which is crosslinkable on its outer cylinder surface by actinic radiation, can be washed out by developers after imagewise exposure and essentially comprises a mixture of at least one elastomeric binder, ethylenically unsaturated, copolymerizable organic compounds, a photoinitiator and, if required, further assistants, wherein a layer sensitive to IR radiation is applied to the surface of the crosslinkable cylinder layer by means of a coating apparatus coaxially with and along the cylinder axis, the coating apparatus comprising a flexible ring element which is adapted to the circumference of the crosslinkable cylinder layer and is in close contact along at least one internal circumference with the circumference of the outer crosslinkable cylinder layer, and the layer sensitive to IR radiation being a layer which is soluble or dispersible in a developer and which contains, in a film-forming binder having elastomeric character, at least one finely distributed substance having a high absorption in the IR wavelength range.

2. A printing medium as claimed in claim 1, wherein the coating apparatus contains at least one elastic O-ring whose inner circumference rests against the outer cylinder layer circumference and which can roll along in the axial direction of the cylinder layer.

3. A printing medium as claimed in claim 1, wherein the coaxial coating apparatus has coaxially arranged dispersion application nozzles facing the surface of the crosslinkable cylindrical layer.

4. A printing medium as claimed in claim 1, wherein the dimensionally stable hollow cylinder is a cast or injection molded, wound or drawn tube element.

5. A printing medium as claimed in claim 1, wherein the viscosity of the applied dispersion is from about 50 to about 500 mPas, in particular from about 100 to 200 mPas.

6. A cylindrical printing medium having a dimensionally stable solid, partly hollow or hollow cylinder with an outer cylinder surface and a plurality of part-layers which are crosslinkable on its outer cylinder surface by actinic radiation, can be washed out by developers after imagewise exposure and essentially comprise a mixture of at least one elastomeric binder, ethylenically unsaturated, copolymerizable organic compounds, a photoinitiator and, if required, further assistants, wherein the part-layers are applied to the surface of the solid, partly hollow or hollow cylinder by means of a coating apparatus coaxially with and along the cylinder axis, the coating apparatus comprising a flexible ring element which is adapted to the circumference of the outer cylinder surface and is in close contact along at least one internal circumference with the circumference of the outer cylinder surface or rests against the surface of the at least one part-layer applied.

7. A printing medium as claimed in claim 6, wherein the coating apparatus contains at least one elastic O-ring whose inner circumference rests against the circumference of the outer cylinder surface or of the applied part-layer(s) and which can roll along in the axial direction of the cylinder.

8. A printing medium as claimed in claim 6, wherein the viscosity of the part-layers to be applied which are crosslinkable by actinic radiation is from about 5000 to about 8000 mPas.

9. A printing medium as claimed in claim 1, wherein the IR radiation-sensitive dispersion layer has a thickness of from about 100 Å to about 2.5 μm.

10. A printing medium as claimed in claim 9, wherein the thickness of the IR radiation-sensitive dispersion layer is from about 1.5 to about 2 μm.

11. A printing medium as claimed in claim 6, wherein a layer which is sensitive to IR radiation and has a thickness of from about 100 Å to about 2.5 μm is applied to the outer circumference of the crosslinkable part-layers.
